(19) United States
(12) Patent Application Publication
(10) Pub. No.: US 2020/0219742 A1
(43) Pub. Date: Jul. 9, 2020

(54) SUBSTRATE TRANSFER DEVICE

(71) Applicant: KAWASAKI JUKOGYO KABUSHIKI KAISHA, Kobe-shi, Hyogo (JP)

(72) Inventor: Takayuki FUKUSHIMA, Takarazuka-shi (JP)

(73) Assignee: KAWASAKI JUKOGYO KABUSHIKI KAISHA, Kobe-shi, Hyogo (JP)

(21) Appl. No.: 16/649,040

(22) PCT Filed: Jul. 30, 2018
(86) PCT No.: PCT/JP2018/028496

§ 371 Date: Mar. 19, 2020

(30) Foreign Application Priority Data
Oct. 2, 2017 (JP) 2017-192693

(51) Int. Cl. H01L 21/673; H01L 21/677; H01L 21/687

(52) U.S. Cl. CPC H01L 21/67313; H01L 21/68714; H01L 21/67742; H01L 21/67766

(57) ABSTRACT

A substrate transfer device including a substrate-grasping hand and a holding member provided on the substrate-grasping hand, the holding member including a claw portion configured to hold a substrate and a support post portion supporting the claw portion. When a force acts on the claw portion the support post portion bends to reduce the force acting on the claw portion.

### TECHNICAL FIELD

The present invention relates to substrate transfer devices.

### BACKGROUND ART

A semiconductor wafer (or semiconductor substrate, which may be simply referred to as a wafer or substrate hereinafter) is produced through a plurality of processes performed in a clean room. The semiconductor wafer is transferred between the process stages by a robot disposed in the clean room.

A semiconductor manufacturing apparatus is known which includes a transfer robot disposed in a clean room and configured to take out a plurality of semiconductor substrates accommodated in slot portions of a quartz boat, place the semiconductor substrates onto respective substrate placement surfaces of a plurality of plates, and transfer the semiconductor substrates to a cassette (see Patent Literature 1, for example).

In the semiconductor manufacturing apparatus disclosed in Patent Literature 1, the transfer robot includes a portion that does not make a swiveling motion or a motion in the forward-rearward (advancing-receding) direction, and this portion is provided with a first sensor configured to detect the presence of placed semiconductor substrates and a second sensor configured to detect improper placement of the semiconductor substrates.

### CITATION LIST

### Patent Literature

PTL 1: Japanese Laid-Open Patent Application Publication No. 2017-85015

### SUMMARY OF INVENTION

### Technical Problem

In the semiconductor manufacturing apparatus disclosed in Patent Literature 1, the second sensor configured to detect improper placement of semiconductor substrates is mounted on that portion of the transfer robot which does not make a swiveling motion or a motion in the forward-rearward (advancing-receding) direction. Thus, when the robot is taking out the semiconductor substrates from the quartz boat, whether the semiconductor substrates are improperly placed cannot be detected.

FIG. 22 is a schematic view showing a situation where a transfer robot makes a motion in the forward/rearward direction while a semiconductor substrate grasped by the transfer robot is improperly placed. In FIG. 22, a part of the transfer robot is omitted.

As shown in FIG. 22, when a transfer robot 300 makes a motion in the forward/rearward direction while a semiconductor substrate 900A grasped by the transfer robot 300 is improperly placed, the improperly placed semiconductor substrate 900A contacts a plate 400A located above the improperly placed semiconductor substrate 900A. The improperly placed semiconductor substrate 900A may contact a plate 400A located therebelow.

When the transfer robot 300 moves further in the forward/rearward direction, the improperly placed semiconductor substrate 900A may be caught on a slot portion 910A of a quartz boat 910, thereby damaging the quartz boat 910.

The present invention has been made to solve the conventional problem described above and aims to provide a substrate transfer device superior to conventional substrate transfer devices in preventing an improperly placed substrate from being caught on a slot portion of a quartz boat and preventing damage to the quartz boat.

### Solution to Problem

To solve the conventional problem described above, a substrate transfer device according to the present invention includes a substrate-grasping hand and a holding member provided on the substrate-grasping hand, the holding member including a claw portion configured to hold a substrate and a support post portion supporting the claw portion, wherein when a force acts on the claw portion, the support post portion bends to reduce the force acting on the claw portion.

In this configuration, when an improperly placed substrate contacts the claw portion located above or below the improperly placed substrate, the support post portion bends to cause the contacted claw portion to move away from the improperly placed substrate. Thus, the substrate transfer device is superior to conventional substrate transfer devices in preventing an improperly placed substrate from being caught on a slot portion of a quartz boat and preventing damage to the quartz boat.

### Advantageous Effects of Invention

The substrate transfer device of the present invention is superior to conventional substrate transfer devices in preventing an improperly placed substrate from being caught on a slot portion of a quartz boat and preventing damage to the quartz boat.

### BRIEF DESCRIPTION OF DRAWINGS

FIG. 1 is a perspective view showing a schematic configuration of a substrate transfer device according to Embodiment 1.

FIG. 2 is a functional block diagram schematically showing a configuration of a control device of the substrate transfer device shown in FIG. 1.

FIG. 3 is a side view of a substrate-grasping hand of the substrate transfer device shown in FIG. 1.

FIG. 4 is a perspective view showing a schematic configuration of holding members of the substrate transfer device shown in FIG. 1.

FIG. 5 is a schematic view showing an example of operations of the substrate transfer device according to Embodiment 1.

FIG. 6 is a schematic view showing an example of operations of the substrate transfer device according to Embodiment 1.

FIG. 7 is a schematic view showing an example of operations of the substrate transfer device according to Embodiment 1.

FIG. 8 is a schematic view showing an example of operations of the substrate transfer device according to Embodiment 1.

FIG. 9 is a schematic view showing a schematic configuration of a holding member of a substrate transfer device of Modified Example 1 based on Embodiment 1.

FIG. 10 is a schematic view showing a schematic configuration of a holding member of a substrate transfer device of Modified Example 2 based on Embodiment 1.

FIG. 11 is a schematic view showing a schematic configuration of a holding member of a substrate transfer device according to Embodiment 2.

FIG. 12 is a schematic view showing a schematic configuration of the holding member of the substrate transfer device according to Embodiment 2.

FIG. 13 is a schematic view showing a schematic configuration of a holding member of a substrate transfer device of Modified Example 1 based on Embodiment 2.

FIG. 14 is a schematic view showing a schematic configuration of the holding member of the substrate transfer device of Modified Example 1 based on Embodiment 2.

FIG. 15 is a schematic view showing a schematic configuration of a holding member of a substrate transfer device of Modified Example 2 based on Embodiment 2.

FIG. 16 is a schematic view showing a schematic configuration of the holding member of the substrate transfer device of Modified Example 2 based on Embodiment 2.

FIG. 17 is a schematic view showing a schematic configuration of the holding member of the substrate transfer device of Modified Example 2 based on Embodiment 2.

FIG. 18 is a schematic view showing a schematic configuration of a holding member of a substrate transfer device according to Embodiment 3.

FIG. 19 is a schematic view showing a schematic configuration of the holding member of the substrate transfer device according to Embodiment 3.

FIG. 20 is a schematic view showing a schematic configuration of a holding member of a substrate transfer device according to Embodiment 4.

FIG. 21 is a schematic view showing a schematic configuration of the holding member of the substrate transfer device according to Embodiment 4.

FIG. 22 is a schematic view showing a situation where a transfer robot makes a motion in a forward/rearward direction while a semiconductor substrate grasped by the transfer robot is improperly placed.

### DESCRIPTION OF EMBODIMENTS

Hereinafter, embodiments of the present invention will be described with reference to the drawings. The same or equivalent elements are denoted by the same reference signs throughout the drawings and will not be described repeatedly. Throughout the drawings, some elements are selectively shown to illustrate the present invention, and other elements may be omitted. The present invention is not limited to the embodiments described below.

### Embodiment 1

A substrate transfer device according to Embodiment 1 includes a substrate-grasping hand and a holding member provided on the substrate-grasping hand, the holding member including a claw portion configured to hold a substrate and a support post portion supporting the claw portion. When a force acts on the claw portion, the support post portion bends to reduce the force acting on the claw portion.

In the substrate transfer device according to Embodiment 1, when a force greater than a first predetermined value acts upwardly on the claw portion, the support post portion may bend to reduce the force acting on the claw portion.

In the substrate transfer device according to Embodiment 1, the support post portion may be configured to return to an original state once the force acting on the claw portion is reduced after the support post portion bends in response to the force acting on the claw portion.

In the substrate transfer device according to Embodiment 1, the support post portion may include a distal portion and a proximal portion, and an elastic member may be attached to the support post portion in such a manner as to cross a boundary between the distal portion and the proximal portion.

In the substrate transfer device according to Embodiment 1, the support post portion may include a distal portion and a proximal portion, and a hinge member may be attached to the support post portion in such a manner as to cross a boundary between the distal portion and the proximal portion.

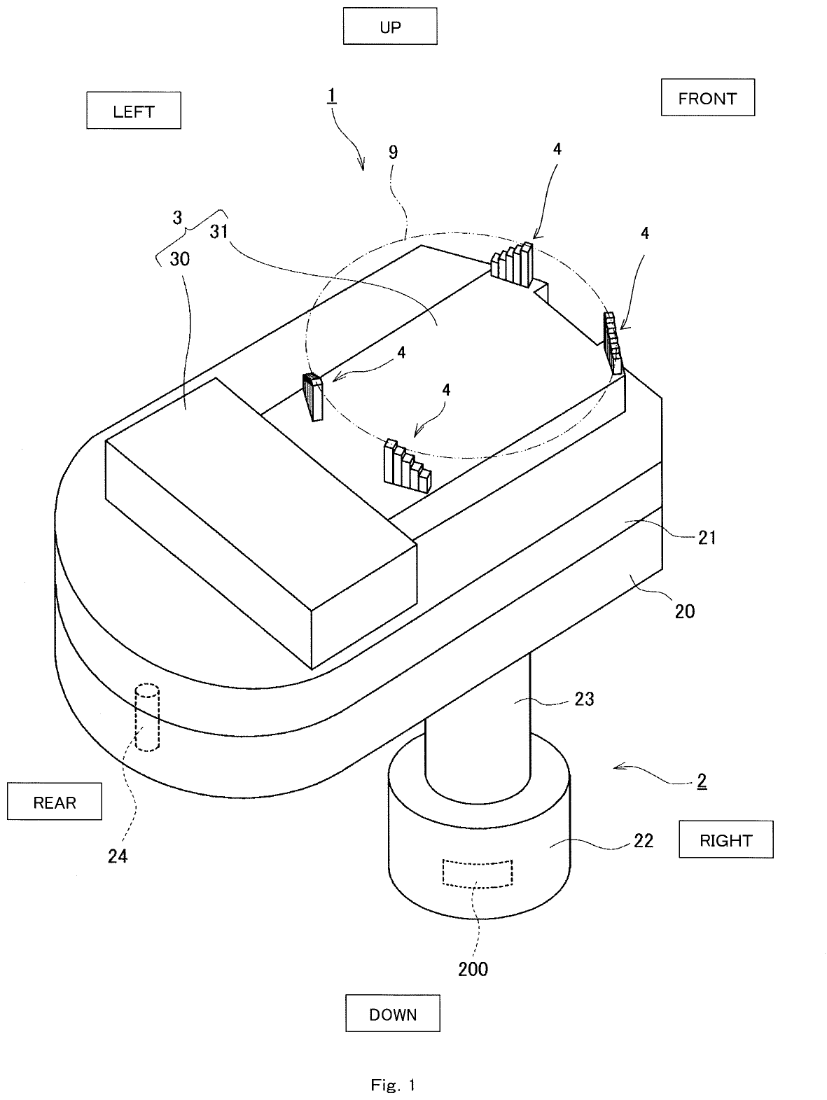

Hereinafter, an example of the substrate transfer device according to Embodiment 1 will be described with reference to FIGS. 1 to 8.

Configuration of Substrate Transfer Device

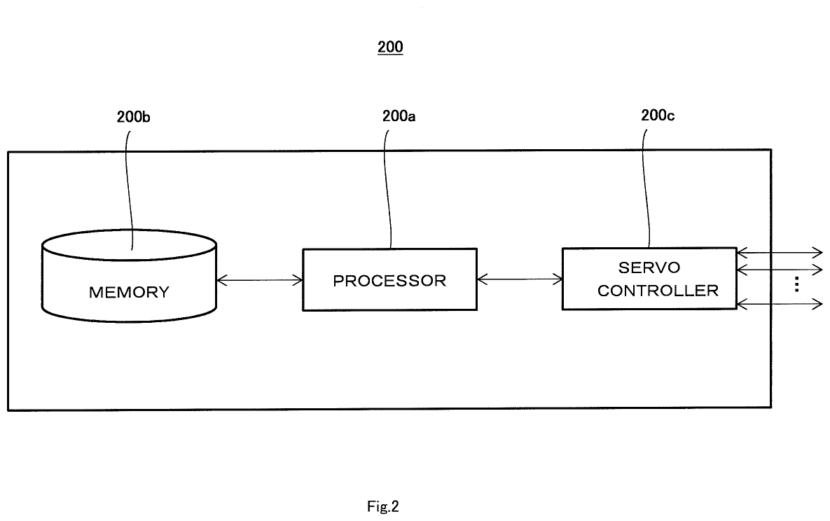

FIG. 1 is a perspective view showing a schematic configuration of the substrate transfer device according to Embodiment 1. FIG. 2 is a functional block diagram schematically showing a configuration of a control device of the substrate transfer device shown in FIG. 1. In FIG. 1, upward/downward, forward/rearward, and leftward/rightward directions defined with respect to the substrate transfer device are shown as upward/downward, forward/rearward, and leftward/rightward directions in the figure.

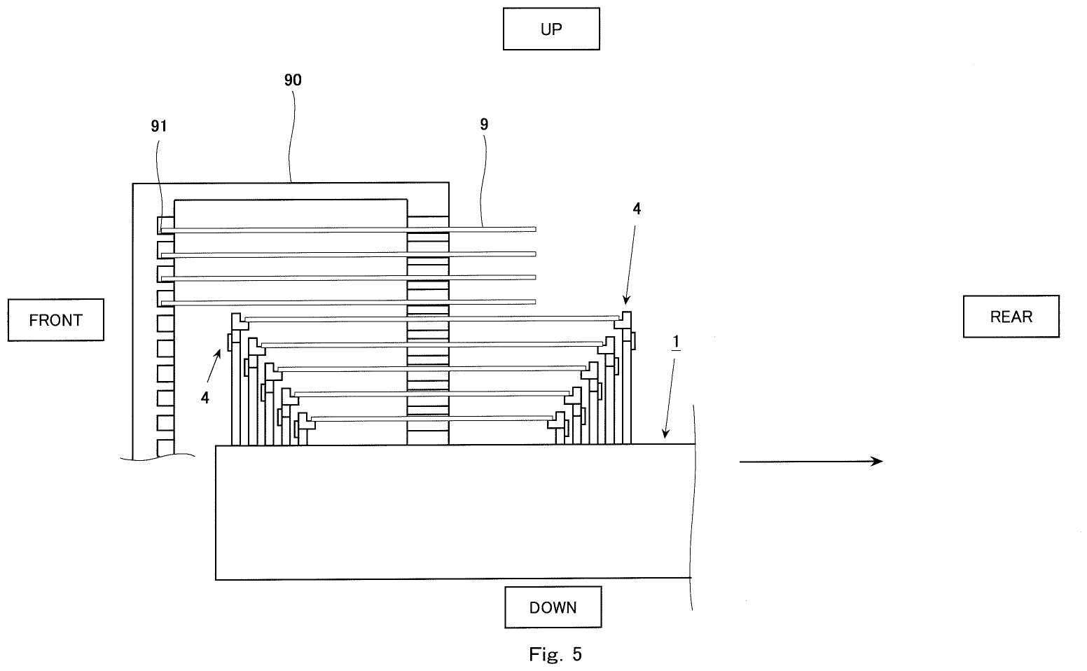

As shown in FIG. 1, the substrate transfer device 1 according to Embodiment 1 includes a manipulator 2, a substrate-grasping hand 3, and a control device 200 and is configured to use holding members 4 to grasp (hold) and transfer substrates 9 accommodated in a quartz boat 90 (see FIG. 5). The details of the configuration of the holding members 4 will be described later.

The substrate 9 may be a circular thin sheet for use as a material of a substrate such as a semiconductor substrate or glass substrate of a semiconductor device. The semiconductor substrate may be, for example, a silicon substrate, a sapphire (single-crystal alumina) substrate, or any other substrate. The glass substrate may be, for example, a glass substrate for a flat panel display (FPD) or a glass substrate for a microelectromechanical system (MEMS).

The following describes the configuration of the manipulator 2 embodied as a horizontal articulated robot. However, the manipulator 2 is not limited to a horizontal articulated robot and may be based on a vertical articulated robot.

The manipulator 2 includes an arm 20, a platform 21, a support base 22, a support shaft 23, and a spindle 24. A control device 200 is disposed in the interior of the support base 22. The control device 200 may be disposed at a location other than the interior of the support base 22.

The support shaft 23 is mounted on the support base 22. The support shaft 23 includes, for example, a ball screw mechanism, a drive motor, a rotation sensor configured to detect the rotational position of the drive motor, and a current sensor configured to detect a current for control of the rotation of the drive motor (all of these are not shown in the drawings). The support shaft 23 is configured to be extendable and retractable in the upward/downward direction and also configured to be pivotable. The drive motor may be, for example, a servo motor servo-controlled by the control device 200. The rotation sensor may be, for example, an encoder.

The lower end of the arm 20 is connected to the upper end of the support shaft 23 such that the arm 20 is pivotable about the axis of a rotational shaft passing through the center of the support shaft 23. The rear end of the platform 21 is connected to the rear end of the arm 20 via the spindle 24 such that the platform 21 is pivotable. On the upper surface of the platform 21 is mounted the substrate-grasping hand 3.

The manipulator 2 includes a drive motor for rotationally moving the platform 21 about the axis of the spindle 24, a power transmission mechanism, a rotation sensor, and a current sensor (all of these are not shown in the drawings). The drive motor may be, for example, a servo motor servo-controlled by the control device 200. The rotation sensor may be, for example, an encoder.

As shown in FIG. 2, the control device 200 includes a processor 200a such as a CPU, a memory 200b such as a ROM or RAM, and a servo controller 200c. The control device 200 is, for example, a robot controller incorporating a computer such as a microcomputer.

The memory 200b stores information such as a basic program for the robot controller and various fixed data. The processor 200a retrieves software such as the basic program stored in the memory 200b and executes the software to control various operations of the manipulator 2. In particular, the processor 200a generates a control command for the manipulator 2 and outputs the control command to the servo controller 200c. The servo controller 200c is configured to, based on the control command generated by the processor 200a, control driving of the servo motors operable to rotate the rotational shafts associated with the support shaft 23 and spindle 24 of the manipulator 2.

The control device 200 may be a single control device 200 that performs centralized control or may be constituted by a plurality of control devices 200 that cooperate together to perform distributed control. While Embodiment 1 employs a configuration in which the memory 200b is included in the control device 200, the present invention is not limited to this configuration. A configuration may be employed in which the memory 200b is provided separately from the control device 200.

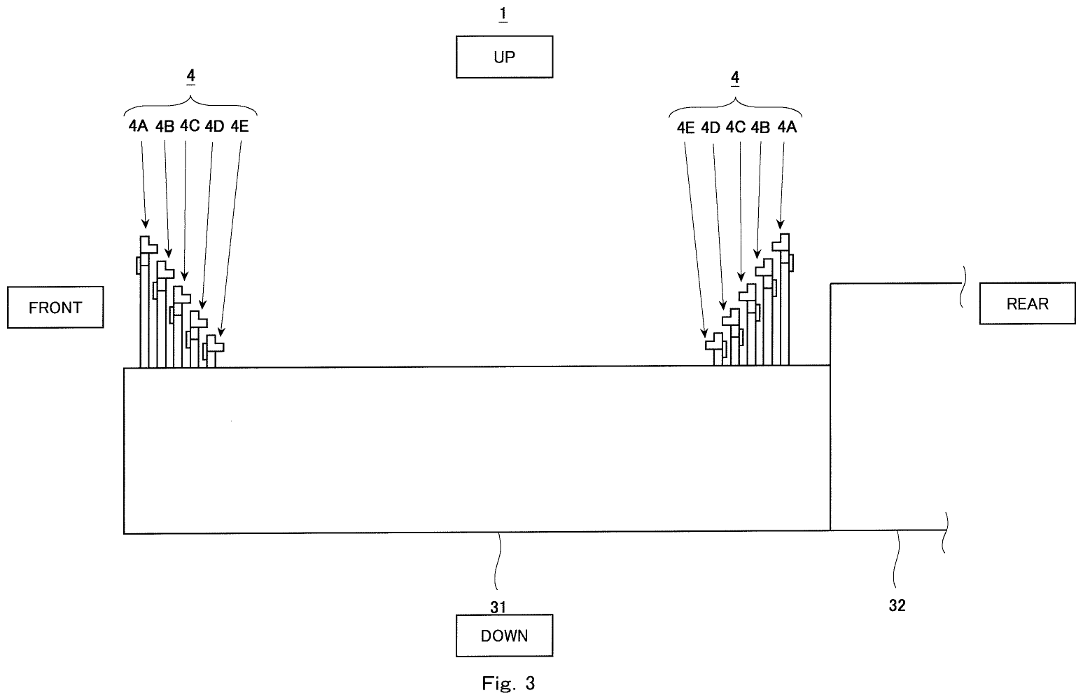

Next, the configuration of the substrate-grasping hand 3 will be described in detail with reference to FIGS. 1 and 3.

FIG. 3 is a side view of the substrate-grasping hand of the substrate transfer device shown in FIG. 1. In FIG. 3, a part of the rear end side of the substrate-grasping hand is omitted. In FIG. 3, upward/downward and forward/rearward directions defined with respect to the substrate transfer device are shown as upward/downward and forward/rearward directions in the figure.

As shown in FIGS. 1 and 3, the substrate-grasping hand 3 includes a first enclosure 31 disposed on the front end side of the platform 21 and a second enclosure 30 disposed on the rear end side of the platform 21. The first enclosure 31 and the second enclosure 30 are connected such that their respective internal spaces are in communication.

On the upper surface of the first enclosure 31 are provided the holding members 4, which are located at left and right edges of the front end (distal end) side of the upper surface and left and right edges of the rear end (proximal end) side of the upper surface. The holding members 4 are configured to be moved by an unillustrated actuator in the forward/rearward and upward/downward directions. At each edge a plurality of holding members 4 (in this embodiment, five holding members 4) are provided. In the following description, the five holding members 4 may be referred to as holding members 4A to 4E, respectively, to distinguish the holding members from one another.

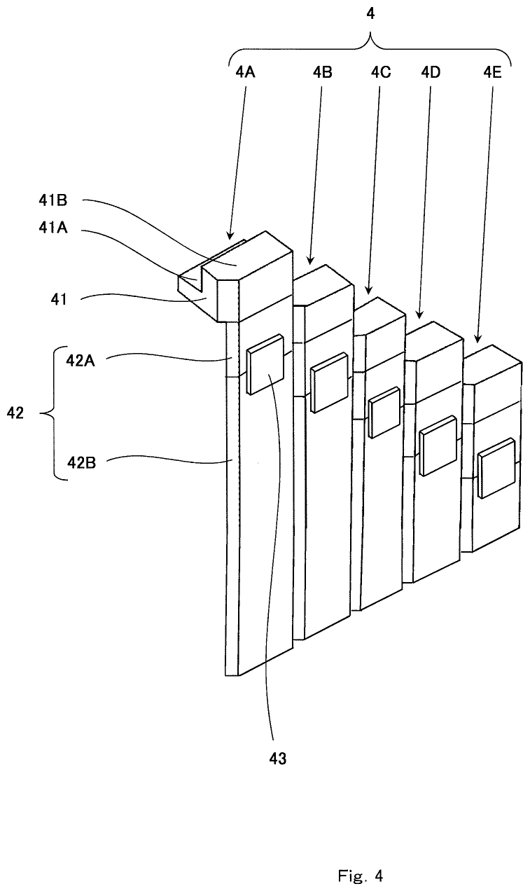

The holding member 4 will now be described in detail with reference to FIGS. 3 and 4.

FIG. 4 is a perspective view showing a schematic configuration of the holding members of the substrate transfer device shown in FIG. 1.

As shown in FIG. 4, each holding member 4 includes a claw portion 41 and a pillar-shaped support post portion 42 (which, in this embodiment, is in the shape of a rectangular prism), and the claw portion 41 is mounted on the distal end of the support post portion 42. The claw portion 41 is approximately L-shaped when viewed in the horizontal direction. In other words, the claw portion 41 is stepped to have a bottom surface 41A and a top surface 41B. A peripheral portion of the lower surface of the substrate 9 is placed on the bottom surface 41A of the claw portion 41.

When a vertical force acts on the claw portion 41, the support post portion 42 bends to reduce the force acting on the claw portion 41. More specifically, the support post portion 42 is configured to bend when a force greater than a first predetermined value acts upwardly on the claw portion 41. The support post portion 42 may be configured to return to the upright state once the vertical force acting on the claw portion 41 is reduced after the support post portion 42 bends in response to the vertical force acting on the claw portion 41.

In particular, the support post portion 42 includes a distal portion 42A and a proximal portion 42B. An elastic member 43 is attached to the support post portion 42 in such a manner as to cross the boundary between the distal portion 42A and the proximal portion 42B. The elastic member 43 may be attached to a portion of the outer surface of the support post portion 42 (the surface facing outwardly from the substrate transfer device 1).

The elastic member 43 is configured to keep the support post portion 42 in the upright state when a force smaller than the first predetermined value is acting upwardly on the claw portion 41 or when no force is acting on the claw portion 41. The elastic member 43 is configured to bend when a force equal to or greater than the first predetermined value acts upwardly on the claw portion 41. Thus, when a force equal to or greater than the first predetermined value acts upwardly on the claw portion 41, the support post portion 42 bends in conjunction with the elastic member 43. Once the force acting on the claw portion 41 is reduced after bending of the support post portion 42, the support post portion 42 returns to the original state (upright state) under the restoring force of the elastic member 43.

The elastic member 43 used may be, for example, a flat spring, a torsion spring, or a rubber material. The first predetermined value can be set beforehand, for example, by an experiment. In view of preventing damage to the slot portions 91 of the quartz boat 90, the first predetermined value may be 0 N.

In Embodiment 1, the holding members 4 are arranged in decreasing order of height from the holding member 4A to the holding member 4E. While Embodiment 1 employs a configuration in which the elastic members 43 are attached to all of the holding members 4A to 4E, the present invention is not limited to this configuration. For example, a configuration may be employed in which the elastic members 43 are attached to the holding members 4A to 4D and no elastic member 43 is attached to the holding member 4E.

While Embodiment 1 employs a configuration in which the elastic member 43 is attached to the support post portion 42 in such a manner as to cross the boundary between the distal portion 42A and the proximal portion 42B, the present invention is not limited to this configuration. A configuration may be employed in which a hinge member is attached to the support post portion 42 in such a manner as to cross the boundary between the distal portion 42A and the proximal portion 42B. The hinge member may be made of any material as long as the hinge member has a bending point and is configured to bend at the bending point. In particular, the hinge member may be a metal hinge or fabric hinge or may be made of a soft material such as a resin.

Further, in the case where the hinge member is attached to the support post portion 42 in such a manner as to cross the boundary between the distal portion 42A and the proximal portion 42B, the support post portion 42 may be configured to return to the original state (upright state) under the weight of the claw portion 41 itself once the force acting on the claw portion 41 is reduced after bending of the support post portion 42.

Operations and Effects of Substrate Transfer Device

Next, operations and effects of the substrate transfer device 1 according to Embodiment 1 will be described with reference to FIGS. 1 to 8. Operations that the manipulator 2 of the substrate transfer device 1 performs in a work consisting of a series of steps are the same as those performed by known manipulators, and will therefore not be described in detail. The operations described below are performed upon retrieval of a program stored in the memory 200b of the control device 200 by the processor 200a of the control device 200.

FIGS. 5 to 8 are schematic views showing examples of operations of the substrate transfer device according to Embodiment 1. In FIGS. 5 to 8, upward/downward and forward/rearward directions defined with respect to the substrate transfer device are shown as upward/downward and forward/rearward directions in the figures. In FIGS. 5 to 8, a part of the quartz boat 90 and a part of the substrate-grasping hand 3 are omitted.

As shown in FIG. 5, the quartz boat 90 is disposed in a work space (e.g., a clean room) in which the substrate transfer device 1 is installed. The quartz boat 90 is provided with a plurality of slot portions 91, and the substrates 9 are placed on the slot portions 91.

It is assumed that instruction information instructing the control device 200 to carry out a work consisting of a series of steps is input to the control device 200 by the operator through an unillustrated input device. In response to this input, the control device 200 causes the manipulator 2 to operate to move the substrate-grasping hand 3 to a location in front of the quartz boat 90. At this time, the control device 200 causes the manipulator 2 to operate such that the substrate-grasping hand 3 is located below the level of the portions where the substrates 9 to be grasped are placed.

Next, the control device 200 causes the manipulator 2 to operate to move the substrate-grasping hand 3 to a location which is inside the quartz boat 90 and below the substrates 9. At this time, the control device 200 causes the substrate-grasping hand 3 to move inside the quartz boat 90 to a location that allows the substrates 9 to be placed on the substrate-grasping hand 3 by a guide portion of the substrate-grasping hand 3.

Next, the control device 200 causes the manipulator 2 to operate to move the substrate-grasping hand 3 upwardly to place the substrates 9 on the bottom surfaces 41A of the claw portions 41 of the holding members 4 and support the substrates 9 from below. Thus, the substrates 9 are held by the substrate-grasping hand 3. If the substrates 9 are properly placed on the bottom surfaces 41A as shown in FIG. 5, no problem will arise during the subsequent rearward movement of the substrate-grasping hand 3.

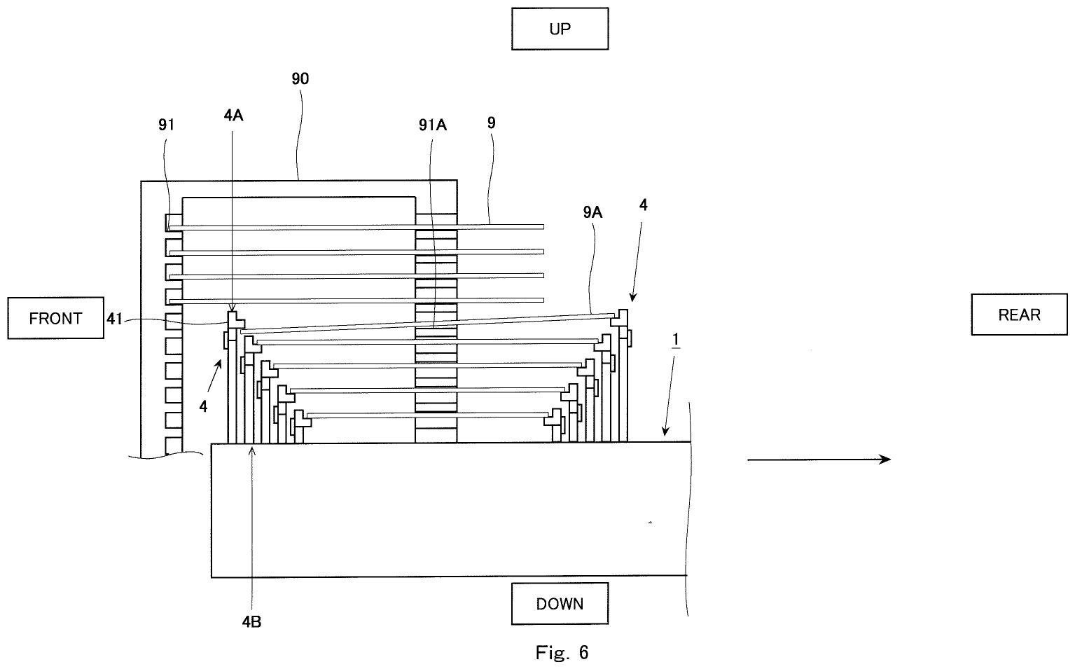

The following discusses an example where, as shown in FIG. 6, a substrate 9A fails to be properly placed on the bottom surface 41A of the holding member 4A and the front edge of the substrate 9A is lowered. In this case, the substrate-grasping hand 3 moves rearward with the substrate 9A in contact with a slot portion 91A. Further, when the substrate-grasping hand 3 moves rearward, the front edge of the substrate 9A may contact the lower surface of the claw portion 41 of the holding member 4A, and the substrate 9A may get caught on the slot portion 91A to cause damage to the slot portion 91A.

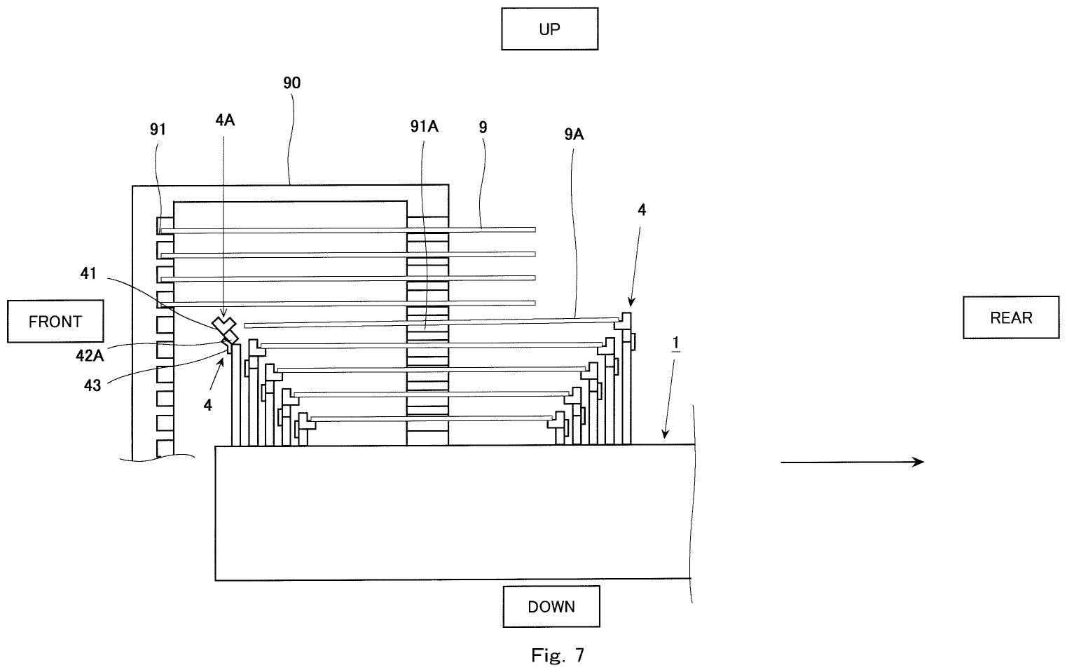

In the substrate transfer device 1 according to Embodiment 1, the support post portion 42 is configured to bend when a force equal to or greater than the first predetermined value acts upwardly on the claw portion 41. As shown in FIG. 7, the elastic member 43 of the holding member 4A bends, and accordingly the support post portion 42 bends to break the contact between the lower surface of the claw portion 41 and the substrate 9A, so that the front edge of the substrate 9A moves upwardly. As a result, the substrate 9A is released from the state of being caught on the slot portion 91A, and damage to the slot portion 91A can be prevented.

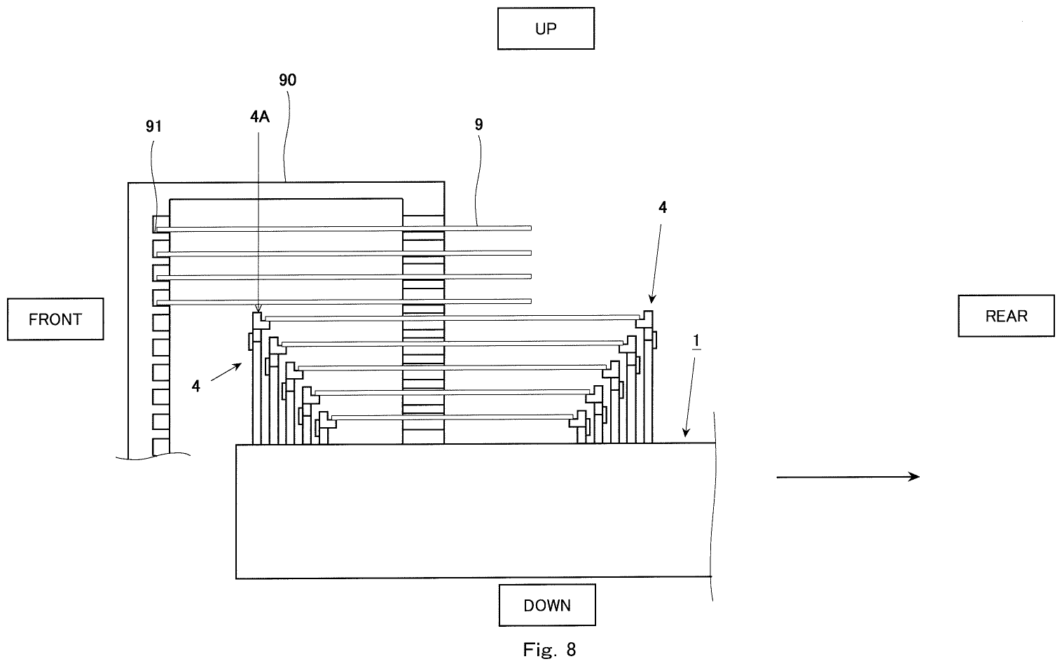

Once the substrate 9A moves upwardly, the force acting on the claw portion 41 is reduced. When the force becomes smaller than the first predetermined value, the elastic member 43 and the support post portion 42 return to the upright state. Consequently, as shown in FIG. 8, the substrate 9A is placed on the bottom surface 41A or top surface 41B (see FIG. 4) of the claw portion 41 of the holding member 4A. As such, the substrate-grasping hand 3 can be properly moved rearward, and damage to the slot portion 91A can be prevented.

### MODIFIED EXAMPLE 1

Next, modified examples of the substrate transfer device according to Embodiment 1 will be described.

In a substrate transfer device of Modified Example 1 based on Embodiment 1, the support post portion is configured to, when a force equal to or greater than a second predetermined value acts downwardly on the claw portion, bend to reduce the force acting on the claw portion.

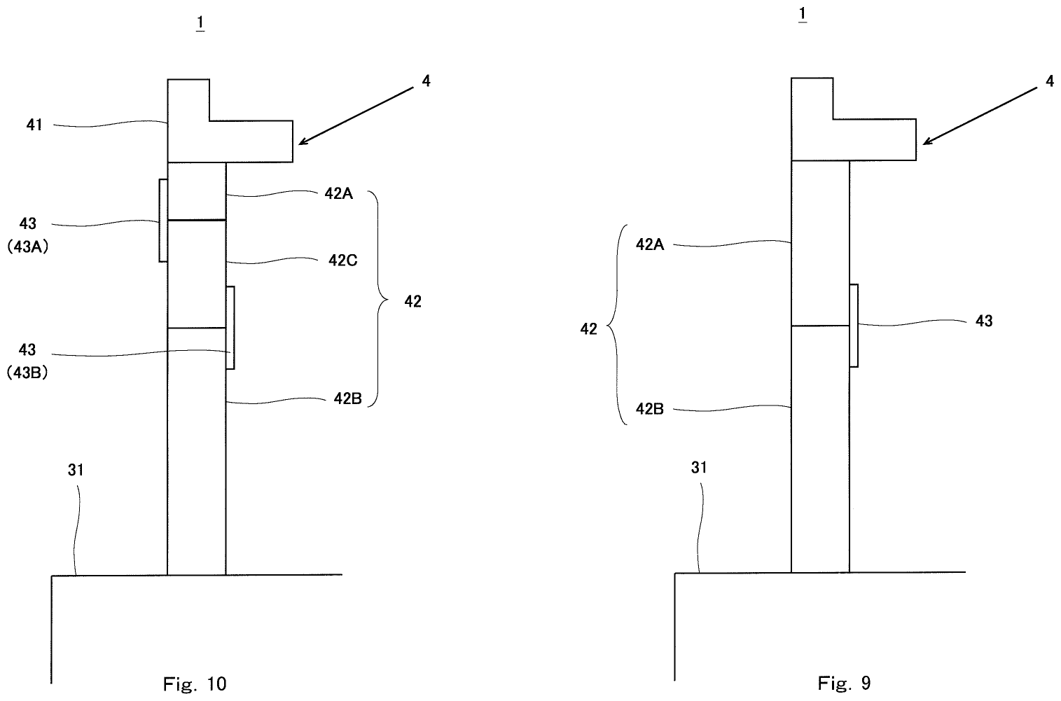

Hereinafter, an exemplary substrate transfer device of Modified Example 1 based on Embodiment 1 will be described with reference to FIG. 9.

FIG. 9 is a schematic view showing a schematic configuration of a holding member of the substrate transfer device of Modified Example 1 based on Embodiment 1.

The substrate transfer device 1 of Modified Example 1 is identical in basic configuration to the substrate transfer device 1 according to Embodiment 1, but differs in that, as shown in FIG. 9, the elastic member 43 is attached to the inner surface of the holding member 4 (the surface facing inwardly).

The elastic member 43 is configured to keep the support post portion 42 in the upright state when a force smaller than the second predetermined value is acting on the claw portion 41 or when no force is acting on the claw portion 41. The elastic member 43 is configured to bend when a force equal to or greater than the second predetermined value acts downwardly on the claw portion 41.

Thus, when a force equal to or greater than the second predetermined value acts downwardly on the claw portion 41, the support post portion 42 bends in conjunction with the elastic member 43. Once the force acting on the claw portion 41 is reduced after bending of the support post portion 42, the support post portion 42 returns to the original state (upright state) under the restoring force of the elastic member 43.

The second predetermined value can be set beforehand, for example, by an experiment. In view of preventing damage to the slot portions 91 of the quartz boat 90, the second predetermined value may be a load corresponding to the weight of one substrate 9, a load corresponding to the total weight of a plurality of substrates 9, or a load corresponding to the total weight of ten substrates 9.

In the substrate transfer device 1 of Modified Example 1 which is configured as described, the support post portion 42 can bend inwardly. As such, for example, when during upward movement of the substrate-grasping hand 3 the claw portion 41 contacts an object such as a slot portion 91 of the quartz boat 90 and is subjected to a downward force equal to or greater than the second predetermined value, the support post portion 42 can bend inwardly to prevent damage to the object such as a slot portion 91 of the quartz boat 90.

### MODIFIED EXAMPLE 2

FIG. 10 is a schematic view showing a schematic configuration of a holding member of a substrate transfer device of Modified Example 2 based on Embodiment 1.

The substrate transfer device 1 of Modified Example 2 is identical in basic configuration to the substrate transfer device 1 according to Embodiment 1, but differs in that, as shown in FIG. 10, the elastic members 43 are attached to both of the outer and inner surfaces of the holding member 4.

Specifically, the support post portion 42 is divided into the distal portion 42A, an intermediate portion 42C, and the proximal portion 42B, and an elastic member 43A is attached to the outer surface of the support post portion 42 in such a manner as to cross the boundary between the distal portion 42A and the intermediate portion 42C. An elastic member 43B is attached in such a manner as to cross the boundary between the intermediate portion 42C and the proximal portion 42B.

Thus, in the substrate transfer device 1 of Modified Example 2, the support post portion 42 can bend not only outwardly but also inwardly. As such, for example, when during upward movement of the substrate-grasping hand 3 the claw portion 41 contacts an object such as a slot portion 91 of the quartz boat 90 and is subjected to a downward force equal to or greater than the second predetermined value, the support post portion 42 can bend inwardly to prevent damage to the object such as a slot portion 91 of the quartz boat 90.

The substrate transfer device 1 of Modified Example 2 which is configured as described above exerts the same effects as the substrate transfer device 1 according to Embodiment 1. Further, in the substrate transfer device 1 of Modified Example 2, as stated above, the support post portion 42 can bend inwardly to prevent damage to an object such as a slot portion 91 of the quartz boat 90 when a force equal to or greater than the second predetermined value acts downwardly on the claw portion 41.

### Embodiment 2

A substrate transfer device according to Embodiment 2 includes the same components as the substrate transfer device according to Embodiment 1 and further includes a sensor configured to detect bending of the support post portion.

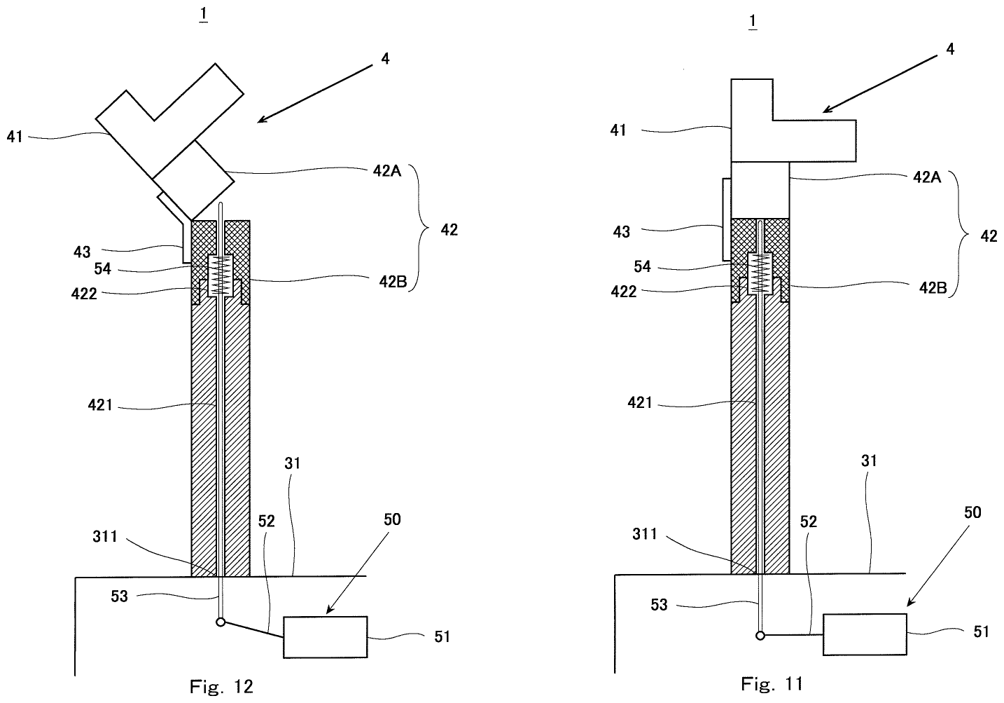

Hereinafter, an example of the substrate transfer device according to Embodiment 2 will be described with reference to FIGS. 11 and 12.

FIGS. 11 and 12 are schematic views showing a schematic configuration of a holding member of the substrate transfer device according to Embodiment 2.

The substrate transfer device 1 according to Embodiment 2 is identical in basic configuration to the substrate transfer device 1 according to Embodiment 1, but differs in that, as shown in FIGS. 11 and 12, the substrate transfer device 1 according to Embodiment 2 further includes a sensor 50 configured to detect bending of the support post portion 42 and output detection information indicating the detection to the control device 200.

Specifically, in Embodiment 2, the sensor 50 is configured as a limit sensor and includes a sensor body 51, a lever 52, a sensor pin 53, and an elastic member 54. The sensor body 51 is disposed in the internal space of the first enclosure 31. The lever 52 is attached to the sensor body 51, and the sensor pin 53 is pivotally connected to the distal end of the lever 52.

The sensor pin 53 is inserted into a through hole 311 provided in the upper surface of the first enclosure 31 and a through hole 421 provided in the proximal portion 42B and communicating with the through hole 311.

The proximal portion 42B includes an internal space 422 communicating with the through hole 421. In the internal space 422 is disposed the elastic member 54 configured to bias the sensor pin 53 upwardly. The elastic member 54 used may be, for example, a compression spring.

As shown in FIG. 11, when the support post portion 42 is in the upright state, the distal end of the sensor pin 53 is in contact with the lower surface of the distal portion 42A. Thus, the sensor pin 53 cannot move upwardly, and the lever 52 connected to the proximal end (lower end) of the sensor pin 53 is in an OFF state, so that the sensor 50 does not detect bending of the support post portion 42.

As shown in FIG. 12, when a force equal to or greater than the first predetermined value acts on the claw portion 41 and accordingly the support post portion 42 bends, the lower surface of the distal portion 42A moves upwardly. Thus, the distal end of the sensor pin 53 is freed, and the sensor pin 53 is moved upwardly by the elastic member 54. This upward movement brings the lever 52 into an ON state, thus allowing the sensor 50 to detect bending of the support post portion 42. The sensor 50 outputs to the control device 200 the detection information indicating that bending of the support post portion 42 has been detected.

Upon receiving the detection information from the sensor 50, the control device 200 may determine that a substrate 9 has been improperly placed and provide information indicating the improper placement to the operator or any other entity. The method for providing the information may be, for example, a method in which linguistic information which reads “A substrate has been improperly placed” is displayed on a monitor, a method in which the linguistic information is output as a voice from a speaker, or a method in which a siren is sounded to notify the operator or any other entity of the improper placement.

While Embodiment 2 employs a configuration in which a limit sensor is used as the sensor 50, the present invention is not limited to this configuration. For example, a configuration may be employed in which a pressure sensor (strain sensor) is used as the sensor 50. In this case, the sensor 50 may be disposed between the upper end surface of the proximal portion 42B and the lower end surface of the distal portion 42A.

The substrate transfer device 1 according to Embodiment 2 which is configured as described exerts the same effects as the substrate transfer device 1 according to Embodiment 1.

### MODIFIED EXAMPLE 1

Next, modified examples of the substrate transfer device 1 according to Embodiment 2 will be described.

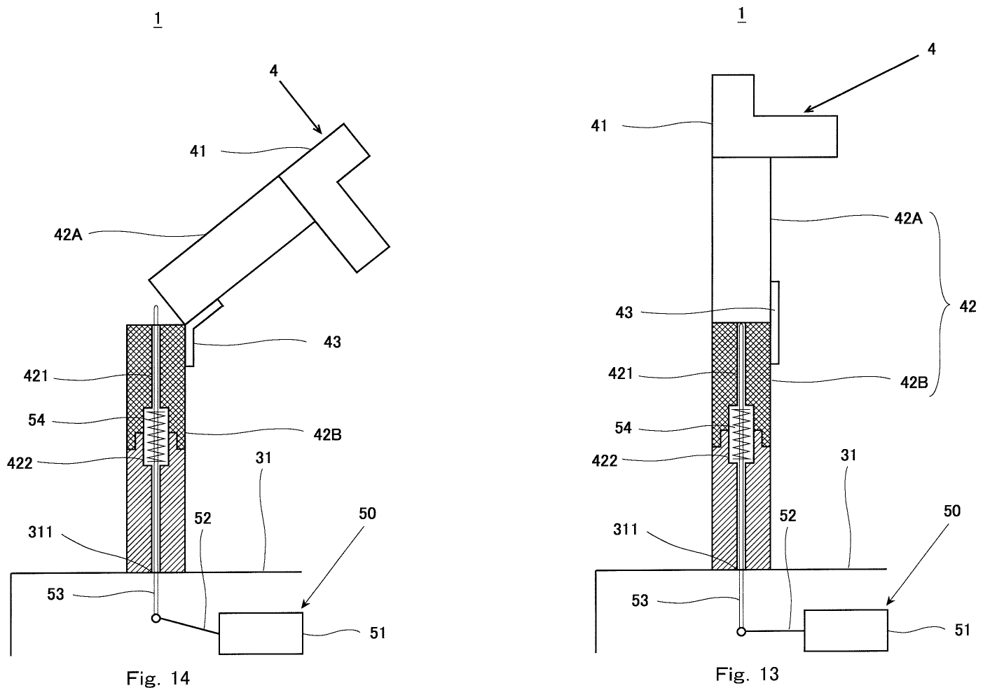

FIGS. 13 and 14 are schematic views showing a schematic configuration of a holding member of a substrate transfer device of Modified Example 1 based on Embodiment 2.

The substrate transfer device 1 of Modified Example 1 based on Embodiment 2 is identical in basic configuration to the substrate transfer device 1 according to Embodiment 2, but differs in that, as shown in FIGS. 13 and 14, the elastic member 43 is attached to the inner surface of the holding member 4 (the surface facing inwardly).

The elastic member 43 is configured to keep the support post portion 42 in the upright state when a force smaller than the second predetermined value is acting on the claw portion 41 or when no force is acting on the claw portion 41. The elastic member 43 is configured to bend when a force equal to or greater than the second predetermined value acts downwardly on the claw portion 41.

Thus, when a force equal to or greater than the second predetermined value acts downwardly on the claw portion 41, the support post portion 42 bends in conjunction with the elastic member 43. Once the force acting on the claw portion 41 is reduced after bending of the support post portion 42, the support post portion 42 returns to the original state (upright state) under the restoring force of the elastic member 43.

In the substrate transfer device 1 of Modified Example 1 which is configured as described above, the support post portion 42 can bend inwardly. As such, for example, when during upward movement of the substrate-grasping hand 3 the claw portion 41 contacts an object such as a slot portion 91 of the quartz boat 90 and is subjected to a downward force equal to or greater than the second predetermined value, the support post portion 42 can bend inwardly to prevent damage to the object such as a slot portion 91 of the quartz boat 90.

### MODIFIED EXAMPLE 2

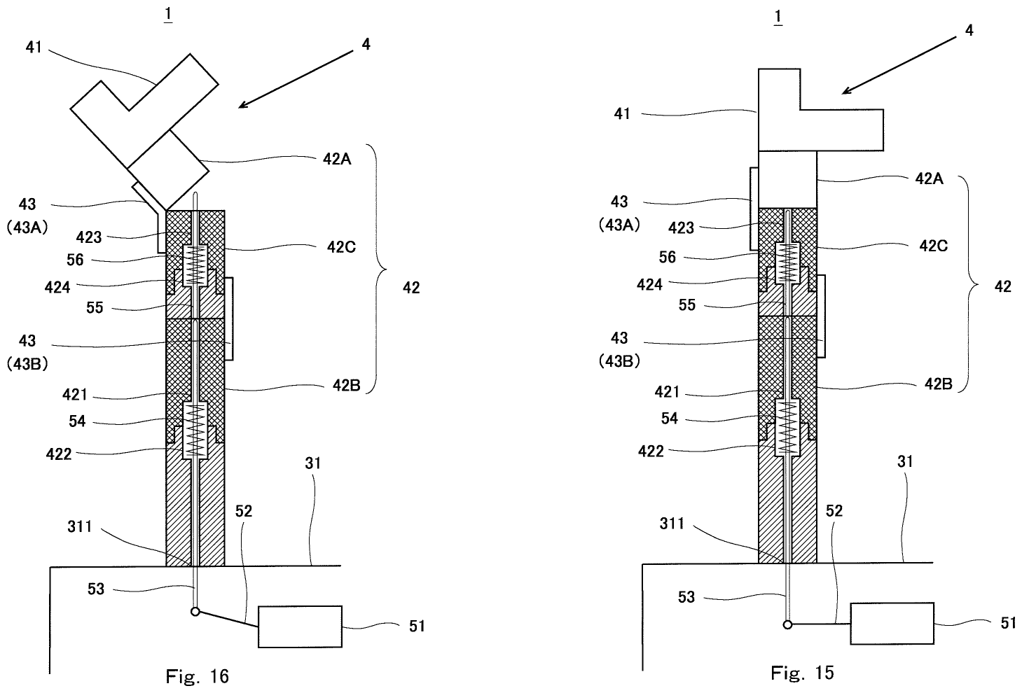

FIGS. 15 to 17 are schematic views showing a schematic configuration of a holding member of a substrate transfer device of Modified Example 2 based on Embodiment 2.

The substrate transfer device 1 of Modified Example 2 based on Embodiment 2 is identical in basic configuration to the substrate transfer device 1 according to Embodiment 2, but differs in that, as shown in FIGS. 15 to 17, the elastic member 43 is attached also to the inner surface of the holding member 4 and that the sensor 50 is configured to detect both outward bending of the support post portion 42 and inward bending of the support post portion 42.

Specifically, the support post portion 42 is divided into the distal portion 42A, an intermediate portion 42C, and the proximal portion 42B, and an elastic member 43A is attached to the outer surface of the support post portion 42 in such a manner as to cross the boundary between the distal portion 42A and the intermediate portion 42C. An elastic member 43B is attached in such a manner as to cross the boundary between the intermediate portion 42C and the proximal portion 42B.

The intermediate portion 42C is provided with a through hole 423 communicating with the through hole 421 of the proximal portion 42B. A sensor pin 55 is inserted into the through hole 423. The through hole 423 of the intermediate portion 42C is divided into two portions, between which is provided an internal space 424 communicating with the two portions of the through hole 423. In the internal space 424 is disposed an elastic member 56 configured to bias the sensor pin 55 upwardly. The elastic member 56 used may be, for example, a compression spring.

As shown in FIG. 15, when the support post portion 42 is in the upright state, the distal end of the sensor pin 55 is in contact with the lower surface of the distal portion 42A. The distal end of the sensor pin 53 is in contact with the proximal end of the sensor pin 55.

Thus, the sensor pin 53 cannot move upwardly, and the lever 52 connected to the proximal end (lower end) of the sensor pin 53 is in an OFF state, so that the sensor 50 does not detect bending of the support post portion 42.

As shown in FIG. 16, when a force equal to or greater than the first predetermined value acts upwardly on the claw portion 41 and accordingly the distal portion 42A bends relative to the intermediate portion 42C, the lower surface of the distal portion 42A moves upwardly. Thus, the distal end of the sensor pin 55 is freed, and the sensor pin 53 is moved upwardly by the elastic member 54. This upward movement brings the lever 52 into an ON state, thus allowing the sensor 50 to detect bending of the support post portion 42. The sensor 50 outputs to the control device 200 the detection information indicating that bending of the support post portion 42 has been detected.

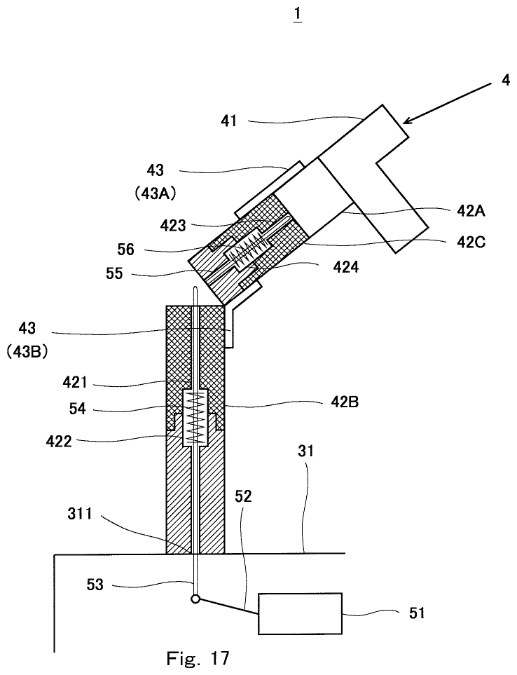

As shown in FIG. 17, when a force equal to or greater than the second predetermined value acts downwardly on the claw portion 41 and accordingly the intermediate portion 42C bends relative to the proximal portion 42B, the lower surface of the intermediate portion 42C and the proximal end of the sensor pin 55 move upwardly. Thus, the distal end of the sensor pin 53 is freed, and the sensor pin 53 is moved upwardly by the elastic member 54. This upward movement brings the lever 52 into an ON state, thus allowing the sensor 50 to detect bending of the support post portion 42. The sensor 50 outputs to the control device 200 the detection information indicating that bending of the support post portion 42 has been detected.

Upon receiving the detection information from the sensor 50, the control device 200 may determine that a substrate 9 has been improperly placed and provide information indicating the improper placement to the operator or any other entity.

The substrate transfer device 1 of Modified Example 2 which is configured as described above exerts the same effects as the substrate transfer device 1 according to Embodiment 2.

In the substrate transfer device 1 of Modified Example 2, when a force equal to or greater than the second predetermined value acts downwardly on the claw portion 41, the support post portion 42 can bend inwardly to prevent damage to an object such as a slot portion 91 of the quartz boat 90.

### Embodiment 3

A substrate transfer device according to Embodiment 3 includes a substrate-grasping hand and a holding member provided on the substrate-grasping hand, the holding member including a claw portion configured to hold a substrate and a support post portion supporting the claw portion. The support post portion includes a distal portion and a proximal portion and is configured such that the distal portion disengages from the proximal portion when a force acts on the claw portion.

In the substrate transfer device according to Embodiment 3, the support post portion may be configured such that the distal portion disengages from the proximal portion when a force greater than a first predetermined value acts upwardly on the claw portion.

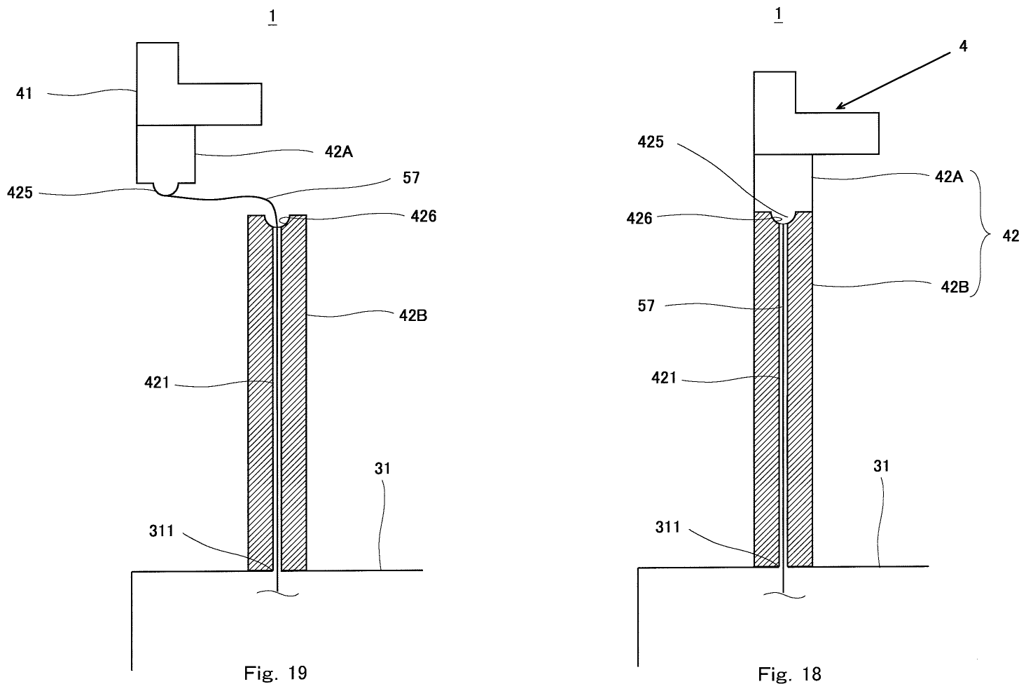

Hereinafter, an example of the substrate transfer device according to Embodiment 3 will be described with reference to FIGS. 18 and 19.

FIGS. 18 and 19 are schematic views showing a schematic configuration of a holding member of the substrate transfer device according to Embodiment 3.

The substrate transfer device 1 according to Embodiment 3 is identical in basic configuration to the substrate transfer device 1 according to Embodiment 1, but differs in that, as shown in FIGS. 18 and 19, the distal portion 42A of the support post portion 42 disengages from the proximal portion 42B of the support post portion 42 when a force acts on the claw portion 41. More specifically, the support post portion 42 is configured such that when a force greater than a first predetermined value acts upwardly on the claw portion 41, the distal portion 42A of the support post portion 42 disengages from the proximal portion 42B of the support post portion 42.

Specifically, a projection 425 is formed on the lower end surface of the distal portion 42A, and a recess 426 is formed in the upper end surface of the proximal portion 42B. The projection 425 and recess 426 are fitted to each other and, when a force equal to or greater than the first predetermined value acts upwardly on the claw portion 41, the projection 425 disengages from the recess 426.

While Embodiment 3 employs a configuration in which the projection 425 is formed on the lower end surface of the distal portion 42A and the recess 426 is formed in the upper end surface of the proximal portion 42B, the present invention is not limited to this configuration. The distal portion 42A and proximal portion 42B may be formed in any shape as long as the portions can be fitted to each other. For example, a configuration may be employed in which the projection 425 is formed on the upper end surface of the proximal portion 42B and the recess 426 is formed in the lower end surface of the distal portion 42A.

The upper surface of the first enclosure 31 is provided with a through hole 311, and the proximal portion 42B is provided with a through hole 421 communicating with the through hole 311. One end of a string member 57 is secured to the lower end of the projection 425. The string member 57 is inserted into the through hole 421 and the through hole 311, and the other end of the string member 57 is secured to a suitable point on the first enclosure 31.

The string member 57 is disposed to have a predetermined length of extra portion located within the first enclosure 31 such that the string member 57 can be drawn out of the through hole 421.

In the substrate transfer device 1 according to Embodiment 3 which is configured as described above, the distal portion 42A is configured to disengage from the proximal portion 42B as shown in FIG. 19 when a force equal to or greater than the first predetermined value acts upwardly on the claw portion 41. Thus, as in the substrate transfer device 1 according to Embodiment 1, the substrate 9 can be released from the state of being caught on a slot portion, and damage to the slot portion can be prevented.

Additionally, in the substrate transfer device 1 according to Embodiment 3, the attachment of the string member 57 to the distal portion 42A can prevent the distal portion 42A and the claw portion 41 from being lost when the distal portion 42A disengages from the proximal portion 42B.

### Embodiment 4

A substrate transfer device according to Embodiment 4 includes the same components as the substrate transfer device according to Embodiment 3 and further includes a sensor configured to detect disengagement of the distal portion of the support post portion from the proximal portion of the support post portion.

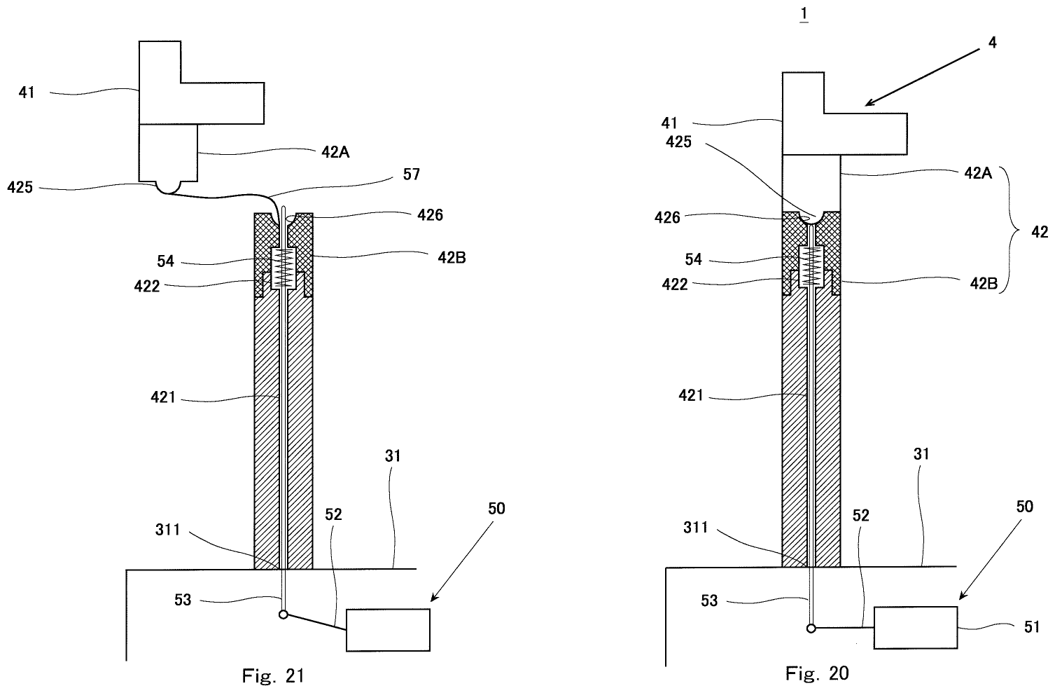

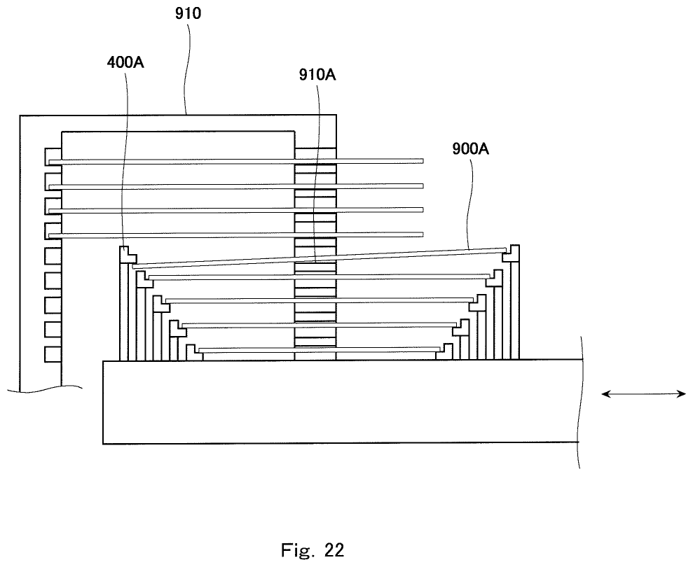

Hereinafter, an example of the substrate transfer device according to Embodiment 4 will be described with reference to FIGS. 20 and 21.

FIGS. 20 and 21 are schematic views showing a schematic configuration of a holding member of the substrate transfer device according to Embodiment 4.

The substrate transfer device 1 according to Embodiment 4 is identical in basic configuration to the substrate transfer device 1 according to Embodiment 3, but differs in that, as shown in FIGS. 20 and 21, the substrate transfer device 1 according to Embodiment 4 further includes a sensor 50 configured to detect disengagement of the distal portion 42A from the proximal portion 42B and output detection information indicating the detection to the control device 200.

Specifically, in Embodiment 4, the sensor 50 is configured as a limit sensor. The configuration of the sensor 50 is the same as that of the sensor 50 in the substrate transfer device 1 according to Embodiment 2, and therefore the details of the configuration will not be described again.

The substrate transfer device 1 according to Embodiment 4 which is configured as described above exerts the same effects as the substrate transfer device 1 according to Embodiment 3.

Many modifications and other embodiments of the present invention will be apparent to those skilled in the art from the foregoing description. Accordingly, the foregoing description is to be construed as illustrative only, and is provided for the purpose of teaching those skilled in the art the best mode for carrying out the invention. The details of the structure and/or function may be varied substantially without departing from the scope of the invention.

### INDUSTRIAL APPLICABILITY

The substrate transfer device of the present invention is superior to conventional substrate transfer devices in preventing an improperly placed substrate from being caught on a slot portion of a quartz boat and preventing damage to the quartz boat. The substrate transfer device of the present invention is therefore useful in the field of industrial robots.

### REFERENCE SIGNS LIST

1 substrate transfer device

2 manipulator

3 substrate-grasping hand

4 holding member

4A holding member

4B holding member

4C holding member

4D holding member

4E holding member

9 substrate

9A substrate

20 arm

21 platform

22 support base

23 support shaft

24 spindle

30 second enclosure

31 first enclosure

41 claw portion

41A bottom surface

41B top surface

42 support post portion

42A distal portion

42B proximal portion

42C intermediate portion

43 elastic member

43A elastic member

43B elastic member

50 sensor

51 sensor body

52 lever

53 sensor pin

54 elastic member

55 sensor pin

56 elastic member

57 string member

90 quartz boat

91 slot portion

91A slot portion

200 control device

200a processor

200b memory

200c servo controller

300 transfer robot

311 through hole

400A plate

421 through hole

422 internal space

423 through hole

424 internal space

425 projection

426 recess

900A semiconductor substrate

910 quartz boat

910A slot portion

1. A substrate transfer device comprising:
a substrate-grasping hand; and
a holding member provided on the substrate-grasping hand, the holding member comprising a claw portion configured to hold a substrate and a support post portion supporting the claw portion, wherein
when a force acts on the claw portion, the support post portion bends to reduce the force acting on the claw portion.

2. The substrate transfer device according to claim 1, wherein when a force greater than a first predetermined value acts upwardly on the claw portion, the support post portion bends to reduce the force acting on the claw portion.

3. The substrate transfer device according to claim 1, wherein when a force equal to or greater than a second predetermined value acts downwardly on the claw portion, the support post portion bends to reduce the force acting on the claw portion.

4. The substrate transfer device according to claim 1, wherein the support post portion is configured to return to an original state once the force acting on the claw portion is reduced after the support post portion bends in response to the force acting on the claw portion.

5. The substrate transfer device according to claim 1, wherein the support post portion comprises a distal portion and a proximal portion, and an elastic member is attached to the support post portion in such a manner as to cross a boundary between the distal portion and the proximal portion.

6. The substrate transfer device according to claim 1, wherein the support post portion comprises a distal portion and a proximal portion, and a hinge member is attached to the support post portion in such a manner as to cross a boundary between the distal portion and the proximal portion.

7. The substrate transfer device according to claim 1 further comprising a sensor configured to detect bending of the support post portion.

8. A substrate transfer device comprising:
a substrate-grasping hand; and
a holding member provided on the substrate-grasping hand, the holding member comprising a claw portion configured to hold a substrate and a support post portion supporting the claw portion, wherein
the support post portion comprises a distal portion and a proximal portion and is configured such that the distal portion disengages from the proximal portion when a force acts on the claw portion.

9. The substrate transfer device according to claim 8, wherein the support post portion is configured such that the distal portion disengages from the proximal portion when a force greater than a first predetermined value acts upwardly on the claw portion.

10. The substrate transfer device according to claim 8, further comprising a sensor configured to detect disengagement of the distal portion of the support post portion from the proximal portion of the support post portion.
